(19) United States
(12) Patent Application Publication
(10) Pub. No.: US 2025/0357445 A1
(43) Pub. Date: Nov. 20, 2025

(54) SEMICONDUCTOR PACKAGE

(71) Applicant: Samsung Electronics Co., Ltd., Suwon-si (KR)

(72) Inventor: Choongbin YIM, Suwon-si (KR)

(73) Assignee: Samsung Electronics Co., Ltd., Suwon-si (KR)

(21) Appl. No.: 19/052,376

(22) Filed: Feb. 13, 2025

(30) Foreign Application Priority Data
May 20, 2024 (KR) 10-2024-0065197

(51) Int. Cl. H01L 25/16; H01L 23/00; H01L 23/14; H01L 23/31; H01L 23/48; H01L 23/522; H01L 23/538; H10B 80/00; H10D 80/30

(52) U.S. Cl. CPC H01L 25/16; H01L 23/14; H01L 23/3128; H01L 23/481; H01L 23/5223; H01L 23/5385; H01L 23/5386; H01L 24/08; H01L 24/16; H01L 24/80; H01L 2224/08225; H01L 2224/16145; H01L 2224/16227; H01L 2224/80895; H01L 2224/80896; H01L 2225/06513; H01L 2225/06517; H01L 2225/06544; H01L 2924/1431; H10B 80/00; H10D 80/30

(57) ABSTRACT

Provided is a semiconductor package including a redistribution substrate, a first semiconductor chip on the redistribution substrate, the first semiconductor chip including first chip upper pads on an upper surface of a first semiconductor substrate, a chip stack on the redistribution substrate, the chip stack being spaced apart from the first semiconductor chip, and an interposer substrate covering an upper surface of the chip stack and an upper surface of the first semiconductor chip. The chip stack may include second semiconductor chips which are vertically stacked, and an uppermost second semiconductor chip among the second semiconductor chips may include second chip upper pads on an upper surface of the uppermost second semiconductor chip. The interposer pads on a lower surface of the interposer substrate may be in contact with the first chip upper pads and the second chip upper pads.

### CROSS-REFERENCE TO RELATED APPLICATIONS

This U.S. non-provisional patent application claims priority under 35 U.S.C. § 119 of Korean Patent Application No. 10-2024-0065197, filed on May 20, 2024, the entire contents of which are hereby incorporated by reference.

### BACKGROUND

The present disclosure herein relates to semiconductor packages.

With development of the electronics industry, demands for higher functionality, higher speed, and smaller size of an electronic component are increasing. In response to such a trend, recent packaging technology is progressing in a direction in which a plurality of semiconductor chips are mounted within one package.

Demands for a portable device are rapidly increasing in a recent electronic product market, and as a result, miniaturization and weight reduction of electronic components mounted in the electronic product is continuously required. Not only technology for reducing an individual size of a mounted component but also technology for integrating multiple individual elements into one package is required to achieve miniaturization and weight reduction of such electronic components.

As a plurality of semiconductor chips included in a semiconductor package are highly integrated, a printed circuit board often fails to accommodate such high integration. In order to alleviate these difficulties, a semiconductor package including an interposer, which is used to connect the semiconductor chips to each other, is being developed.

### SUMMARY

The present disclosure provides semiconductor packages having improved electrical characteristics and methods for manufacturing the same.

The present disclosure also provides a miniaturized semiconductor package.

The purposes of the present disclosure are not limited to the above-mentioned purposes, and other purposes not mentioned would be clearly understood by those skilled in the art from the disclosure below.

Some example embodiments of the inventive concepts provide a semiconductor package including a redistribution substrate, a first semiconductor chip mounted on the redistribution substrate, the first semiconductor chip including first chip upper pads provided on an upper a redistribution substrate; a first semiconductor chip on the redistribution substrate, the first semiconductor chip including first chip upper pads on an upper surface of a first semiconductor substrate; a chip stack on the redistribution substrate, the chip stack being spaced apart from the first semiconductor chip; and an interposer substrate covering an upper surface of the chip stack and an upper surface of the first semiconductor chip, wherein the chip stack includes second semiconductor chips which are vertically stacked, and an uppermost second semiconductor chip among the second semiconductor chips includes second chip upper pads on an upper surface of the uppermost second semiconductor chip, the interposer substrate includes interposer pads on a lower surface of the interposer substrate, and the interposer pads are in contact with the first chip upper pads and the second chip upper pads.

In some example embodiments of the inventive concepts, a semiconductor package includes a substrate; a first semiconductor chip and a chip stack spaced apart from each other on the substrate; and an interposer substrate on upper surfaces of the first semiconductor chip and the chip stack, wherein the first semiconductor chip includes, a first through via penetrating a first semiconductor substrate, a first integrated circuit on a first active surface of the first semiconductor substrate, and a first chip pad on a first inactive surface of the first semiconductor substrate, the chip stack includes second semiconductor chips stacked in a direction perpendicular to an upper surface of the substrate, the second semiconductor chips each include, a second through via penetrating a second semiconductor substrate, a second integrated circuit on a second active surface of the second semiconductor substrate, and a second chip pad on a second inactive surface of the second semiconductor substrate, the interposer substrate includes a capacitor device in the interposer substrate and interposer pads on a lower surface of the interposer substrate, and some of the interposer pads are in contact with the first chip pad, and remaining interposer pads are in contact with the second chip pad of the chip stack.

In some example embodiments of the inventive concepts, a semiconductor package includes a substrate; an external connection terminal on a lower surface of the substrate; a redistribution substrate on an upper surface of the substrate; a first semiconductor chip on the redistribution substrate, the first semiconductor chip including first chip pads on an upper surface of the first semiconductor chip; a chip stack on the redistribution substrate and spaced apart from the first semiconductor chip; and an interposer substrate covering an upper surface of the chip stack and the upper surface of the first semiconductor chip, wherein the chip stack includes second semiconductor chips which are vertically stacked, and an uppermost second semiconductor chip among the second semiconductor chips includes second chip pads on an upper surface of the uppermost second semiconductor chip, the interposer substrate includes, an interposer interconnection layer, an interposer core on the interposer interconnection layer, at least one capacitor device in the interposer interconnection layer, and interposer pads on a lower surface of the interposer interconnection layer, the capacitor device includes, an upper electrode, a lower electrode spaced apart from the upper electrode, a dielectric film between the upper electrode and the lower electrode, and an upper electrode pad on an upper surface of the upper electrode, and the upper electrode pad is electrically connected to the capacitor device and an interconnection pattern in the interposer interconnection layer.

### BRIEF DESCRIPTION OF THE FIGURES

The accompanying drawings are included to provide a further understanding of the inventive concepts, and are incorporated in and constitute a part of this specification. The drawings illustrate embodiments of the inventive concept and, together with the description, serve to explain principles of the inventive concept. In the drawings:

FIG. 1 is a plan view illustrating a semiconductor package according to some example embodiments of the inventive concepts;

FIG. 2 is a cross-sectional view, taken along line A-A′ of FIG. 1, illustrating a semiconductor package according to some example embodiments of the inventive concepts;

FIGS. 3 and 4 are enlarged views, of portion P1 of FIG. 2, for partially describing a semiconductor package according to some example embodiments of the inventive concepts;

FIGS. 5 and 6 are cross-sectional views for describing a semiconductor package according to some example embodiments of the inventive concepts;

FIGS. 7 and 8 are enlarged views, of portion P2 of FIG. 6, for partially describing a semiconductor package according to some example embodiments of the inventive concepts;

FIG. 9 is a cross-sectional view illustrating a semiconductor package according to some example embodiments of the inventive concepts; and

FIGS. 10 to 13 are cross-sectional views for describing a method for manufacturing a semiconductor package according to some example embodiments of the inventive concepts.

### DETAILED DESCRIPTION

Hereinafter, semiconductor packages according to the inventive concepts will be described with reference to the drawings.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

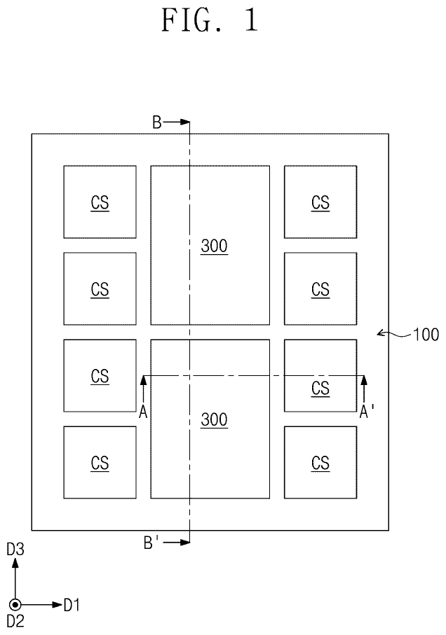

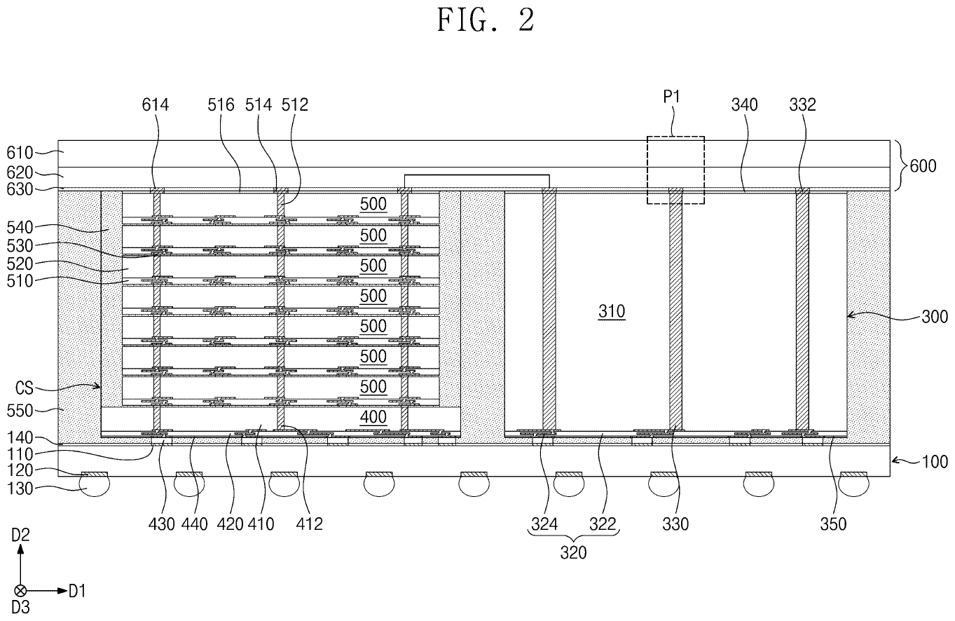

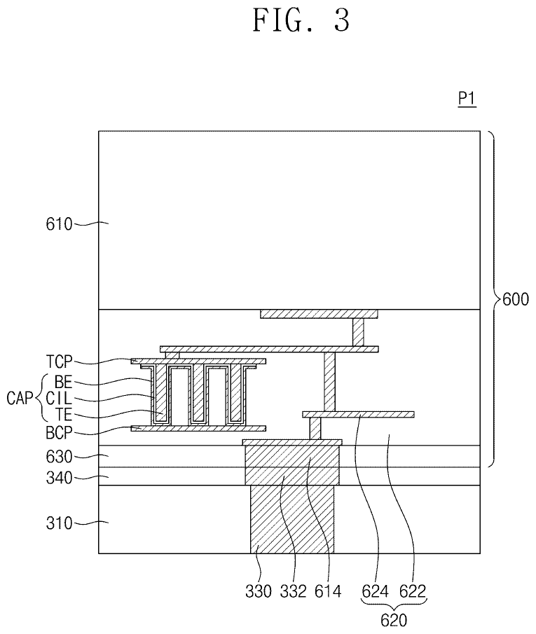

FIG. 1 is a plan view illustrating a semiconductor package according to some example embodiments of the inventive concepts. FIG. 2 is a cross-sectional view, taken along line A-A′ of FIG. 1, illustrating a semiconductor package according to some example embodiments of the inventive concepts. FIG. 3 is an enlarged view, of portion P1 of FIG. 2, for partially describing a semiconductor package according to some example embodiments of the inventive concepts.

Referring to FIGS. 1 to 3, a semiconductor package according to some example embodiments of the inventive concepts may include a first substrate 100, first semiconductor chips 300, and chip stacks CS. As used herein, a first direction D1 may be defined as a direction parallel to an upper surface of the first substrate 100. A second direction D2 may be a direction perpendicular to the upper surface of the first substrate 100 and perpendicular to the first direction D1. A third direction D3 may be defined as a direction parallel to the upper surface of the first substrate 100 and perpendicular to the first direction D1 and the second direction D2. A first semiconductor chip 300 may be provided in plurality on the first substrate 100. The first semiconductor chips 300 may be spaced apart on the first substrate 100 in the third direction D3. A chip stack CS may be provided in plurality on the first substrate 100. The chip stacks CS may be provided on a first side of the first semiconductor chips 300 in the first direction D1 and an opposite side of the first semiconductor chips 300 in the first direction D1. At least one chip stack CS may be disposed in each of the first direction D1 and the opposite direction of the first direction D1 of the first semiconductor chips 300. In other words, the chip stacks CS may be disposed in at least two lines extending in the third direction D3. The two lines of the chip stacks CS may be spaced apart from each other in the first direction D1. The first semiconductor chips 300 may be provided between the two lines of the chip stacks CS.

FIG. 1 illustrates that the semiconductor package includes the first semiconductor chips 300 and the chip stacks CS, but the inventive concepts are not limited thereto. One first semiconductor chip 300 and one chip stack CS may be provided on the first substrate 100. Here, the first semiconductor chip 300 and the chip stack CS may be spaced apart from each other on the first substrate 100. Alternatively, the first semiconductor chip 300 and a plurality of chip stacks CS may be provided. For example, the chip stacks CS may be spaced apart from each other in the third direction D3 and disposed on one side of the first semiconductor chip 300. Thus, numbers and arrangement of first semiconductor chips 300 and chip stacks CS may vary as needed. Hereinafter, description will be continued on the basis of the example embodiments of FIG. 1.

The first substrate 100 may be a redistribution substrate. For example, although not shown, the first substrate 100 may include one substrate interconnection layer or at least two stacked substrate interconnection layers. As used herein, a substrate interconnection layer may refer to an interconnection layer formed by patterning each of one insulating material layer and one conductive material layer. Each of the substrate interconnection layers may include an insulating pattern and a conductive pattern in the insulating pattern. The conductive pattern of any one substrate interconnection layer may be electrically connected to the conductive pattern of another adjacent substrate interconnection layer.

The first substrate 100 may have upper first substrate pads 110. The upper first substrate pads 110 may be an upper portion of the conductive pattern of an uppermost substrate interconnection layer among the substrate interconnection layers or separate pads electrically connected to the conductive pattern in the substrate interconnection layer. The upper first substrate pads 110 may be disposed on the upper surface of the first substrate 100. The upper first substrate pads 110 may protrude onto the upper surface of the first substrate 100. However, the inventive concepts are not limited thereto, and the upper first substrate pads 110 may be coplanar with the upper surface of the first substrate 100 and exposed on the first substrate 100.

It is described with reference to FIG. 1 that the first substrate 100 is a redistribution substrate, but the inventive concepts are not limited thereto. According to other example embodiments, the first substrate 100 may be a printed circuit board (PCB). Here, the first substrate 100 may have an internal interconnection pattern provided in the first substrate 100. For example, the first substrate 100 may have a structure in which an insulating pattern and the internal interconnection pattern are alternately stacked. Here, the upper first substrate pads 110 may be separate pads electrically connected to the internal interconnection pattern or a portion of the internal interconnection pattern protruding onto the upper surface of the first substrate 100. Hereinafter, description will be continued on the basis of the example embodiments of FIG. 1.

Lower first substrate pads 120 and substrate connection terminals 130 may be provided on a lower surface of the first substrate 100. The lower first substrate pads 120 may be separate pads disposed on the lower surface of the first substrate 100 and connected to the conductive pattern of the first substrate 100 or a portion of the conductive pattern exposed onto the lower surface of the first substrate 100. However, the inventive concepts are not limited thereto, and the lower first substrate pads 120 may protrude onto the lower surface of the first substrate 100. The substrate connection terminals 130 may be each disposed on a lower surface of a corresponding lower first substrate pad 120. The substrate connection terminals 130 may include a solder ball, solder bump, or the like.

A first insulating film 140 may be provided on the upper surface of the first substrate 100. The first insulating film 140 may cover the upper surface of the first substrate 100. The first insulating film 140 may surround the upper first substrate pads 110, on the first substrate 100. The upper first substrate pads 110 may be exposed onto an upper surface of the first insulating film 140. The first insulating film 140 may include silicon oxide (SiOx), silicon nitride (SiNx), or the like.

The first semiconductor chips 300 may be disposed on the upper surface of the first substrate 100. Hereinafter, for convenience of description, components of the first semiconductor chips 300 will be described on the basis of one first semiconductor chip 300. The first semiconductor chip 300 may be provided in a face-down form on the first substrate 100. The first semiconductor chip 300 may include a first semiconductor substrate 310. The first semiconductor substrate 310 may have an active surface and an inactive surface. Hereinafter, as used herein, an active surface may be defined as a surface on which an integrated device or integrated circuits are formed in a semiconductor chip, and an inactive surface may be defined as an opposite surface opposed to the active surface. A lower surface of the first semiconductor substrate 310 may be the active surface of the first semiconductor substrate 310. The first semiconductor substrate 310 may include a semiconductor material. For example, the first semiconductor substrate 310 may include silicon (Si). The integrated device or integrated circuits may be provided on the active surface of the first semiconductor substrate 310, that is, the lower surface of the first semiconductor substrate 310. The integrated device or the integrated circuits may include a logic circuit. That is, the first semiconductor chip 300 may be a logic chip.

A first interconnection layer 320 may be provided on the active surface of the first semiconductor substrate 310. The first interconnection layer 320 may have a first insulating pattern 322 and a first interconnection pattern 324 provided in the first insulating pattern 322. The first insulating pattern 322 may cover the integrated device or the integrated circuits, on the lower surface of the first semiconductor chip 300. The first interconnection pattern 324 may be connected to the integrated device or the integrated circuits formed on the first semiconductor substrate 310. The first interconnection pattern 324 may include a conductive material such as metal. For example, the first interconnection pattern 324 may include copper (Cu). The first insulating pattern 322 may include oxide such as silicon oxide (SiOx).

The first semiconductor substrate 310 may include first through vias 330 penetrating the first semiconductor substrate 310. The first through vias 330 may penetrate the first semiconductor substrate 310 in a direction perpendicular to the upper surface of the first substrate 100. One end of each of the first through vias 330 may be in contact with an upper surface of the first interconnection layer 320. The first through vias 330 may be connected to the first interconnection pattern 324 of the first interconnection layer 320. The other end of each of the first through vias 330 may be exposed onto the inactive surface of the first semiconductor substrate 310. First chip upper pads 332 may be provided on the inactive surface of the first semiconductor substrate 310. The first chip upper pads 332 may be connected to the first through vias 330. The first chip upper pads 332 may be respectively in contact with upper surfaces of first through vias 330 corresponding thereto. The first through vias 330 may connect the first chip upper pads 332 and the first interconnection layer 320. The first chip upper pads 332 may be electrically connected to the first interconnection pattern 324 of the first interconnection layer 320 through the first through vias 330. The first chip upper pads 332 and the first through vias 330 may include a conductive material. For example, the first chip upper pads 332 and the first through vias 330 may include copper (Cu). A second insulating film 340 may be provided on the inactive surface of the first semiconductor substrate 310. The second insulating film 340 may cover the inactive surface of the first semiconductor substrate 310. The second insulating film 340 may surround the first chip upper pads 332, on the first semiconductor substrate 310. The first chip upper pads 332 may be exposed onto an upper surface of the second insulating film 340. The second insulating film 340 may include silicon oxide (SiOx), silicon nitride (SiNx), or the like.

The first semiconductor chip 300 may further include first chip lower pads provided on the lower surface of the first semiconductor chip 300. The first chip lower pads may be a portion of the first interconnection pattern 324 protruding onto the lower surface of the first semiconductor chip 300, or separate pads disposed on a lower surface of the first insulating pattern 322 and connected to the first interconnection pattern 324. A third insulating film 350 covering the lower surface of the first semiconductor chip 300 may be provided. The third insulating film 350 may cover the lower surface of the first semiconductor chip 300. The third insulating film 350 may surround the first chip lower pads, on the lower surface of the first semiconductor chip 300. The first chip lower pads may be exposed onto a lower surface of the third insulating film 350. The third insulating film 350 may include silicon oxide (SiOx), silicon nitride (SiNx), or the like.

First connection terminals such as solder balls or solder bumps may be provided on lower surfaces of the first chip lower pads. One end of each of the first connection terminals may be respectively in contact with the first chip lower pads. The first connection terminals may be electrically connected to the first interconnection pattern 324 in the first semiconductor chip 300. The first semiconductor chip 300 may be mounted on the first substrate 100 by using the first connection terminals. The other end of each of the first connection terminals may be in contact with the first substrate 100. Specifically, the other end of each of the first connection terminals may be electrically connected to the conductive pattern of the first substrate 100. The first connection terminals may be provided between the upper surface of the first substrate 100 and the lower surface of the first semiconductor chip 300 and may connect the first substrate 100 and the first semiconductor chip 300. The first interconnection pattern 324 may be electrically connected to the first substrate 100 through the first chip lower pads and the first connection terminals.

The chip stacks CS may be provided on the upper surface of the first substrate 100. The chip stacks CS may be spaced apart, on the first substrate 100, from the first semiconductor chips 300 in the first direction D1 or an opposite direction of the first direction D1. The chip stacks CS may each include a base chip 400, second semiconductor chips 500 stacked on the base chip 400, and a first molding film 540 surrounding the second semiconductor chips 500. Hereinafter, for convenience of description, components of the chip stacks CS will be described on the basis of one chip stack CS.

The base chip 400 may be provided in a face-down form on the first substrate 100. The base chip 400 may include a base substrate 410. The base substrate 410 may be a semiconductor substrate. For example, the base substrate 410 may be a wafer-level semiconductor substrate made of a semiconductor material such as silicon (Si). A lower surface of the base substrate 410 may be an active surface of the base substrate 410. Specifically, an integrated device or integrated circuits may be provided to the active surface of the base substrate 410, that is, the lower surface of the base substrate 410. For example, the integrated device or the integrated circuits may include a memory circuit. That is, the base chip 400 may be a memory chip such as DRAM, SRAM, MRAM, or flash memory. On the other hand, the integrated device or the integrated circuits may include a logic circuit. In this case, the base chip 400 may be a logic chip.

The base chip 400 may include a base circuit layer 420 and a base through via 412. The base circuit layer 420 may be provided on a lower surface of the base chip 400. The base circuit layer 420 may include the integrated device or the integrated circuit. The base through via 412 may penetrate the base chip 400 in the second direction D2. The base through via 412 and the base circuit layer 420 may be electrically connected to each other.

The base chip 400 may further include base pads, a fourth insulating film 440, and second connection terminals 430. The base pads may be pads disposed on the lower surface of the base chip 400 and connected to the base circuit layer 420 of the base chip 400. The base pads may be electrically connected to the integrated device or the integrated circuit. The fourth insulating film 440 covering the lower surface of the base chip 400 may be provided. The fourth insulating film 440 may cover the lower surface of the base chip 400. The fourth insulating film 440 may surround the base pads, on the lower surface of the base chip 400. The base pads may be exposed onto a lower surface of the fourth insulating film 440. The fourth insulating film 440 may include silicon oxide (SiOx), silicon nitride (SiNx), or the like. Each of the second connection terminals 430 may be disposed on a lower surface of each of the base pads corresponding thereto. The second connection terminals 430 may be solder balls or solder bumps. The second connection terminals 430 may be electrically connected to the integrated device or the integrated circuit.

A second semiconductor chip 500 may be provided on the base chip 400. A width of the second semiconductor chip 500 may be smaller than a width of the base chip 400. Thicknesses of the base chip 400 and second semiconductor chip 500 of the chip stack CS may be smaller than a thickness of the first semiconductor chip 300.

The second semiconductor chip 500 may be provided in a face-down form on the first substrate 100. The second semiconductor chip 500 may include a second semiconductor substrate 510. The second semiconductor substrate 510 may be a semiconductor substrate. For example, the second semiconductor substrate 510 may include silicon (Si). A lower surface of the second semiconductor substrate 510 may be an active surface. Specifically, an integrated device or integrated circuits may be provided to the active surface of the second semiconductor substrate 510, that is, the lower surface of the second semiconductor substrate 510. For example, the integrated device or the integrated circuits may include a memory circuit. That is, the second semiconductor chip 500 may be a memory chip such as DRAM, SRAM, MRAM, or flash memory.

The second semiconductor chip 500 may include a second circuit layer 520 and second through vias 512. The second circuit layer 520 may be provided on the active surface of the second semiconductor substrate 510. The second circuit layer 520 may include the integrated device or the integrated circuit. The second through vias 512 may penetrate the second semiconductor chip 500 in the second direction D2. The second through vias 512 and the second circuit layer 520 may be electrically connected. Connection bumps 530 may be provided on a lower surface of the second semiconductor chip 500. The connection bumps 530 may include a solder ball, solder bump, or the like. The connection bumps 530 may electrically connect, between the base chip 400 and the second semiconductor chip 500, the base chip 400 and the second semiconductor chip 500. The connection bumps 530 may be electrically connected to the integrated device or the integrated circuit of the second circuit layer 520.

The second semiconductor chip 500 may be provided in plurality. For example, the plurality of second semiconductor chips 500 may be stacked on the base chip 400. Eight to thirty-two second semiconductor chips 500 may be stacked. The connection bumps 530 may be each provided between the second semiconductor chips 500. The connection bumps 530 may be connected to the second through vias 512 of another second semiconductor chip 500 disposed thereunder. Although not shown, adhesive layers may be provided between the second semiconductor chips 500. The adhesive layers may include a non-conductive film (NCF). The adhesive layers may surround the connection bumps 530, between the second semiconductor chips 500, and prevent or reduce in likelihood an electrical short between the connection bumps 530. FIG. 2 illustrates that the second semiconductor chips 500 are connected by using the connection bumps 530, but the inventive concepts are not limited thereto. According to other example embodiments, the second semiconductor chips 500 may be directly connected to each other. For example, the second through vias 512 of the second semiconductor chips 500 may be directly connected to a chip pad or an interconnection pattern of the second circuit layer 520 of another second semiconductor chip 500 disposed thereon.

A thickness of an uppermost second semiconductor chip 500 may be the same as or greater than thicknesses of other second semiconductor chips 500 disposed thereunder. However, the inventive concepts are not limited thereto. Second chip upper pads 514 may be provided on an inactive surface of an uppermost second semiconductor substrate 510. The second chip upper pads 514 may be respectively connected to upper surfaces of the second through vias 512, corresponding thereto, of the uppermost second semiconductor chip 500. The second chip upper pads 514 may be electrically connected to the second circuit layer 520 through the second through vias 512. The second chip upper pads 514 may include a conductive material. For example, the second chip upper pads 514 may include copper (Cu). FIG. 2 illustrates that the uppermost second semiconductor chip 500 has the second chip upper pads 514, but the inventive concepts are not limited thereto. The second chip upper pads 514 may be provided on an upper surface of each of the second semiconductor chips 500. A fifth insulating film 516 may be provided on the upper surface of the uppermost second semiconductor chip 500.

The fifth insulating film 516 may cover the upper surface of the uppermost second semiconductor chip 500. The fifth insulating film 516 may surround the second chip upper pads 514, on the uppermost second semiconductor chip 500. Upper surfaces of the second chip upper pads 514 may be exposed onto an upper surface of the fifth insulating film 516. The fifth insulating film 516 may include silicon oxide (SiOx), silicon nitride (SiNx), or the like.

The first molding film 540 may be disposed on an upper surface of the base chip 400. The first molding film 540 may cover the upper surface of the base chip 400. The first molding film 540 may surround the second semiconductor chips 500. An upper surface of the first molding film 540 may be coplanar with the upper surface of the fifth insulating film 516. The first molding film 540 may include an insulating polymer material. For example, the first molding film 540 may include an epoxy molding compound (EMC).

The chip stack CS may be mounted on the first substrate 100. For example, the chip stack CS may be connected to the upper first substrate pads 110 disposed on the upper surface of the first substrate 100 through the second connection terminals 430 of the base chip 400. The second connection terminals 430 may be in contact with the upper surfaces of the upper first substrate pads 110 and a lower surface of the base circuit layer 420 and electrically connect the chip stack CS and the first substrate 100.

A second molding film 550 may be provided on the first substrate 100. The second molding film 550 may cover the upper surface of the first substrate 100. The second molding film 550 may surround the first semiconductor chips 300 and the chip stacks CS, on the first substrate 100. The second molding film 550 may fill a space between the first semiconductor chips 300 and the chip stacks CS. An upper surface of the second molding film 550 may be coplanar with upper surfaces of the first semiconductor chips 300 and upper surfaces of the chip stacks CS. The second molding film 550 may include an insulating material. For example, the second molding film 550 may include an epoxy molding compound (EMC).

An interposer substrate 600 may be provided on the upper surfaces of the first semiconductor chips 300 and the chip stacks CS. The interposer substrate 600 may cover the upper surfaces of the first semiconductor chips 300 and the chip stacks CS. The interposer substrate 600 may be in contact with the upper surfaces of the first semiconductor chips 300 and the upper surfaces of the chip stacks CS. The upper surfaces of the first semiconductor chips 300 and the upper surfaces of the chip stacks CS may be located at the same vertical level. The interposer substrate 600 may vertically overlap all of the first semiconductor chips 300 and the chip stacks CS.

The interposer substrate 600 may include an interposer core 610 and an interposer interconnection layer 620 on a lower surface of the interposer core 610. The interposer core 610 may include a semiconductor material. For example, the interposer core 610 may include silicon (Si). The interposer interconnection layer 620 may be provided on the lower surface of the interposer core 610. The interposer interconnection layer 620 may have an interposer insulating pattern 622 and an interposer interconnection pattern 624 provided in the interposer insulating pattern 622. A height of the interposer substrate 600 may be about 40 μm to about 70 μm. A width of the interposer substrate 600 in the first direction D1 and the third direction D3 may be each about 40 μm to about 100 μm. However, the inventive concepts are not limited thereto, and the width of the interposer substrate 600 in the first direction D1 and the third direction D3 may vary according to arrangement of the first semiconductor chips 300 and the chip stacks CS.

A capacitor device CAP may be located in the interposer interconnection layer 620. The capacitor device CAP may be located above any one of the first semiconductor chips 300. For example, the capacitor device CAP may vertically overlap the first semiconductor chip 300. However, the inventive concepts are not limited thereto, and the capacitor device CAP may be provided in plurality. The capacitor devices CAP may be respectively located above the first semiconductor chips 300. Alternatively, the capacitor devices CAP may be located above the chip stacks CS and the first semiconductor chips 300. Hereinafter, components of the capacitor devices CAP will be described on the basis of one capacitor device CAP.

The capacitor device CAP may be formed in the interposer insulating pattern 622. The capacitor device CAP may include a multilayer ceramic (MLC) capacitor device. However, the inventive concepts are not limited thereto, and various types of capacitor devices may be included as needed. The capacitor device CAP may be electrically connected to the interposer interconnection pattern 624 through an upper electrode pad TCP. The upper electrode pad TCP may be connected to the interposer interconnection pattern 624 through a via. The upper electrode pad TCP may have a plate shape. The capacitor device CAP may be provided on a lower surface of the upper electrode pad TCP. The capacitor device CAP may be in contact with the upper electrode pad TCP. The capacitor device CAP may be electrically connected to the interposer interconnection pattern 624 through the upper electrode pad TCP.

The capacitor device CAP may include a lower electrode BE, an upper electrode TE, and a capacitor dielectric film CIL between the lower electrode BE and the upper electrode TE. A height of the capacitor device CAP may be about 1 μm to about 5 μm. The upper electrode TE may be provided in plurality. The plurality of upper electrodes TE may have a shape of a pillar perpendicularly extending from the upper electrode pad TCP. The upper electrodes TE may have uniform widths and heights. Lower surfaces of the upper electrodes TE may be substantially coplanar with each other. The upper electrodes TE may be arranged in various forms. For example, the upper electrodes TE may be spaced apart from each other on the lower surface of the upper electrode pad TCP. Alternatively, the upper electrodes TE may be arranged in a form of a zigzag or honeycomb. Arranging the upper electrodes TE in a form of a zigzag or honeycomb may be advantageous in increasing diameters of the upper electrodes TE and improve integration density of the upper electrodes TE. The upper electrodes TE may be electrically connected to the upper electrode pad TCP in common. The upper electrodes TE may be in contact, for example direct contact, with and connected to the lower surface of the upper electrode pad TCP. However, the inventive concepts are not limited thereto, and the upper electrodes TE may be connected to the upper electrode pad TCP through vias disposed on upper surfaces of the upper electrodes TE.

The capacitor dielectric film CIL and the lower electrode BE may be sequentially located on the upper electrodes TE. The capacitor dielectric film CIL and the lower electrode BE may cover the lower surfaces and side surfaces of the upper electrodes TE. The capacitor dielectric film CIL may be located between the upper electrodes TE and the lower electrode BE. The capacitor dielectric film CIL may cover the upper electrodes TE with a uniform thickness and fill a space between the upper electrodes TE and the lower electrode BE. The capacitor dielectric film CIL may cover the lower surfaces and side surfaces of the upper electrodes TE, and the lower surface of the upper electrode pad TCP exposed between the upper electrodes TE. The capacitor dielectric film CIL may extend from an outer side surface of the upper electrodes TE to the lower surface of the upper electrode pad TCP and partially cover the lower surface of the upper electrode pad TCP. A thickness of the capacitor dielectric film CIL may be smaller than thicknesses of the upper electrodes TE and the lower electrode BE. The capacitor dielectric film CIL may include a single layer of any one selected from a combination of metal oxide such as HfO2, ZrO2, Al2O3, La2O3, Ta2O3, and/or TiO2 and/or a piezo-electric material having a perovskite structure such as SrTiO3(STO), (Ba,Sr)TiO3(BST), BaTiO3, PZT, PLZT, or a combination of such layers.

The lower electrode BE may be located on the capacitor dielectric film CIL. The lower electrode BE may conformally cover the capacitor dielectric film CIL. On the other hand, the lower electrode BE may fill a space between the upper electrodes TE, on the capacitor dielectric film CIL. In a case in which the upper electrodes TE are provided in plurality, one lower electrode BE may cover the plurality of upper electrodes TE. That is, the upper electrodes TE may share one lower electrode BE. The upper electrodes TE and the lower electrode BE may include a film of high-melting-point metal such as cobalt, titanium, nickel, tungsten, and molybdenum, and/or a metal nitride film such as a titanium nitride (TiN) film, a titanium silicon nitride (TiSiN) film, a titanium aluminum nitride (TiAlN) film, a tantalum nitride (TaN) film, a tantalum silicon nitride (TaSiN) film, a tantalum aluminum nitride (TaAlN) film, and/or a tungsten nitride (WN) film.

A lower electrode pad BCP may be disposed on the lower surfaces of the upper electrodes TE. An upper surface of the lower electrode pad BCP may be in contact with the lower electrode BE. The lower electrode BE may be electrically connected to the lower electrode pad BCP. The lower electrode pad BCP may have a plate shape. Although not shown, the lower electrode pad BCP may be electrically connected to the interposer interconnection pattern 624. The lower electrode pad BCP may include various metal materials such as copper (Cu), aluminum (al), nickel (Ni), and/or the like.

Lower interposer pads 614 may be provided on a lower surface of the interposer interconnection layer 620. The lower interposer pads 614 may be a portion of the interposer interconnection pattern 624 protruding onto a lower surface of the interposer substrate 600, or separate pads disposed on a lower surface of the interposer insulating pattern 622 and connected to the interposer interconnection pattern 624. A sixth insulating film 630 may be provided on the lower surface of the interposer interconnection layer 620. The sixth insulating film 630 may cover the lower surface of the interposer interconnection layer 620. The sixth insulating film 630 may surround the lower interposer pads 614, on the interposer interconnection layer 620. The lower interposer pads 614 may be exposed onto a lower surface of the sixth insulating film 630. The lower surface of the sixth insulating film 630 may be in contact with the upper surfaces of the first molding film 540 and the second molding film 550. The sixth insulating film 630 may include silicon oxide (SiOx), silicon nitride (SiNx), or the like.

As shown, the first chip upper pads 332 or the second chip upper pads 514 may be respectively connected to the lower interposer pads 614. Hereinafter, for convenience of description, connection relationship of the interposer substrate 600, and the first semiconductor chips 300 and the chip stacks CS will be described on the basis of one first semiconductor chip 300 and one chip stack CS.

The first chip upper pads 332 may be connected to lower surfaces of some of the lower interposer pads 614. The second chip upper pads 514 may be connected to lower surfaces of the remaining lower interposer pads 614. The second insulating film 340 of the first semiconductor chip 300 and the sixth insulating film 630 of the interposer substrate 600 may be bonded to each other on an interface of the first semiconductor chip 300 and the interposer substrate 600. Here, the second insulating film 340 and the sixth insulating film 630 may form oxide, nitride, or oxynitride hybrid bonding. As used herein, hybrid bonding represents bonding through which two components including a material of the same type fuse at an interface thereof. For example, the second insulating film 340 and the sixth insulating film 630 bonded to each other may have a continuous configuration, and a boundary surface between the second insulating film 340 and the sixth insulating film 630 may not be viewed. The second insulating film 340 and the sixth insulating film 630 may be formed of the same material and provided as one component. That is, the second insulating film 340 and the sixth insulating film 630 may be bonded to each other and integrally formed. However, the inventive concepts are not limited thereto. The second insulating film 340 and the sixth insulating film 630 may be formed of different materials, and the second insulating film 340 and the sixth insulating film 630 may not have a continuous configuration.

The first semiconductor chip 300 and the interposer substrate 600 may be in contact with each other. The first chip upper pads 332 of the first semiconductor chip 300 and the lower interposer pads 614 of the interposer substrate 600 may be in contact, for example direct contact, with each other on an interface of the first semiconductor chip 300 and the interposer substrate 600. For example, the first chip upper pads 332 and the lower interposer pads 614 may form intermetallic hybrid bonding. The first chip upper pads 332 and the lower interposer pads 614 bonded to each other may have a continuous configuration, and a boundary surface between the first chip upper pads 332 and the lower interposer pads 614 may not be viewed. For example, the first chip upper pads 332 and the lower interposer pads 614 may be formed of the same material and provided as one component. For example, the first chip upper pads 332 and the lower interposer pads 614 may be bonded to each other and integrally formed. Hereinafter, bonding the first chip upper pads 332 and the lower interposer pads 614 will be described in more detail on the basis of one first chip upper pad 332 and one lower interposer pad 614.

A width of the first chip upper pad 332 may be the same as a width of the lower interposer pad 614. FIG. 1 illustrates that the width of the first chip upper pad 332 is the same as the width of the lower interposer pad 614, but the inventive concept is not limited thereto. Any one of the width of the first chip upper pad 332 or the width of the lower interposer pad 614 may be greater than the other. Here, at least some of the lower interposer pads 614 may vertically overlap at least some of the first chip upper pads 332. A planar shape of the first chip upper pad 332 may be the same as a planar shape of the lower interposer pad 614. The planar shape of the first chip upper pad 332 and the planar shape of the lower interposer pad 614 may be a circle or a quadrangle. However, the inventive concepts are not limited thereto.

The fifth insulating film 516 of the chip stack CS and the sixth insulating film 630 of the interposer substrate 600 may be bonded to each other on an interface of the chip stack CS and the interposer substrate 600. Here, the fifth insulating film 516 and the sixth insulating film 630 may form oxide, nitride, or oxynitride hybrid bonding. The fifth insulating film 516 and the sixth insulating film 630 bonded to each other may have a continuous configuration, and a boundary surface between the fifth insulating film 516 and the sixth insulating film 630 may not be viewed. The fifth insulating film 516 and the sixth insulating film 630 may be formed of the same material and provided as one component. That is, the fifth insulating film 516 and the sixth insulating film 630 may be bonded to each other and integrally formed. However, the inventive concepts are not limited thereto. The fifth insulating film 516 and the sixth insulating film 630 may be formed of different materials, and the fifth insulating film 516 and the sixth insulating film 630 may not have a continuous configuration.

The chip stack CS and the interposer substrate 600 may be in contact with each other. The second chip upper pads 514 of the chip stack CS and the lower interposer pads 614 of the interposer substrate 600 may be in contact, for example direct contact, with each other on an interface of the chip stack CS and the interposer substrate 600. For example, the second chip upper pads 514 and the lower interposer pads 614 may form intermetallic hybrid bonding. The second chip upper pads 514 and the lower interposer pads 614 bonded to each other may have a continuous configuration, and a boundary surface between the second chip upper pads 514 and the lower interposer pads 614 may not be viewed. For example, the second chip upper pads 514 and the lower interposer pads 614 may be formed of the same material and provided as one component. For example, the second chip upper pads 514 and the lower interposer pads 614 may be bonded to each other and integrally formed. Hereinafter, bonding the second chip upper pads 514 and the lower interposer pads 614 will be described in more detail on the basis of one second chip upper pad 514 and one lower interposer pad 614.

A width of the second chip upper pad 514 may be the same as a width of the lower interposer pad 614. FIG. 1 illustrates that the width of the second chip upper pad 514 is the same as the width of the lower interposer pad 614, but the inventive concept is not limited thereto. Any one of the width of the second chip upper pad 514 or the width of the lower interposer pad 614 may be greater than the other. Here, at least some of the lower interposer pads 614 may vertically overlap at least some of the second chip upper pads 514. A planar shape of the second chip upper pad 514 may be the same as a planar shape of the lower interposer pad 614. The planar shape of the second chip upper pad 514 and the planar shape of the lower interposer pad 614 may be a circle or a quadrangle. However, the inventive concepts are not limited thereto.

The interposer substrate 600 may be hybrid bonded to the first semiconductor chips 300 and the chip stacks CS, and thus the interposer substrate 600 may electrically connect the chip stacks CS and the first semiconductor chips 300. For example, the first chip upper pads 332 of the first semiconductor chips 300 may be respectively connected to the lower interposer pads 614. The first interconnection layer 320 of the first semiconductor chips 300 may be electrically connected to the interposer interconnection pattern 624 in the interposer interconnection layer 620 through the first through vias 330, the first chip upper pads 332, and the lower interposer pads 614. The interposer interconnection pattern 624 may electrically connect the first semiconductor chips 300 each other. Similarly, the interposer interconnection pattern 624 may electrically connect, in the interposer interconnection layer 620, the chips stacks CS to each other or electrically connect the chips stacks CS and the first semiconductor chips 300.

Referring to FIG. 2, the capacitor device CAP in the interposer substrate 600 may vertically overlap the first semiconductor chip 300. The capacitor device CAP may be connected to the lower interposer pads 614 through the interposer interconnection pattern 624, and thus electrically connected to the chip stacks CS and the first semiconductor chips 300. That is, the capacitor device CAP may be located adjacent to and electrically connected to the chip stacks CS and the first semiconductor chips 300. Accordingly, power transfer efficiency and signal transfer efficiency of the chip stacks CS and the first semiconductor chips 300 may be increased. Thus, a semiconductor package having improved electrical characteristics may be provided.

In addition, the interposer substrate 600 having the interposer core 610 may be provided on the upper surfaces of the chip stacks CS and the first semiconductor chips 300, and thus heat generated by the chip stacks CS and the first semiconductor chips 300 may be transferred to the outside through the interposer substrate 600. For example, heat generated by the chip stacks CS and the first semiconductor chips 300 may be transferred to the interposer core 610 through the interposer interconnection layer 620. The heat may be dissipated to the outside through the interposer core 610. In particular, the interposer core 610 may have higher thermal conductivity than the interposer interconnection layer 620, and the chip stacks CS and the first semiconductor chips 300 may rapidly dissipate heat in an upward direction from the interposer substrate 600 through the interposer core 610 thereon. That is, a semiconductor package having improved heat dissipation characteristics may be provided.

It is described with reference to FIGS. 1 to 3 that the interposer substrate 600 has the interposer core 610 and the interposer interconnection layer 620, but the inventive concepts are not limited thereto. The interposer substrate 600 may be a redistribution substrate. For example, although not shown, the interposer substrate 600 may include one substrate interconnection layer or at least two substrate interconnection layers which are stacked. Each of the substrate interconnection layers may include an insulating pattern and a conductive pattern in the insulating pattern. The conductive pattern of any one substrate interconnection layer may be electrically connected to the conductive pattern of another adjacent substrate interconnection layer. Here, the interposer substrate 600 may not include the interposer core 610. The capacitor device CAP may be provided in the insulating pattern of the substrate interconnection layer. The capacitor device CAP may be electrically connected to the conductive pattern, in the insulating pattern.

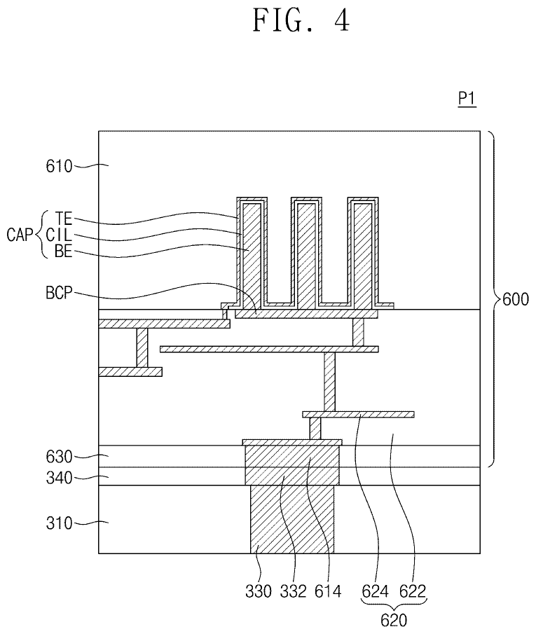

It is described with reference to FIG. 3 that the capacitor device CAP is provided in the interposer interconnection layer 620, but the inventive concepts are not limited thereto. FIG. 4 is an enlarged view, of portion P1 of FIG. 2, for partially describing a semiconductor package according to some example embodiments of the inventive concepts.

Referring to FIG. 4, the capacitor device CAP may be provided in the interposer core 610. A configuration and a structure of the capacitor device CAP may be substantially the same as or similar to those described with reference to FIG. 3. For example, the capacitor device CAP may include the lower electrode BE, the upper electrode TE, and the capacitor dielectric film between the lower electrode BE and the upper electrode TE. However, unlike FIG. 3, the lower electrode BE may be provided in plurality. The lower electrodes BE may have a shape of a pillar perpendicularly extending from the lower electrode pad BCP. Upper surfaces of the lower electrodes BE may be substantially coplanar with each other. In this case, the capacitor dielectric film CIL and the upper electrode TE may be located on the upper surface and side surfaces of the lower electrode BE. Lower surfaces of the lower electrodes BE may be substantially coplanar with each other and may be in contact, for example direct contact, with and electrically connected to an upper surface of the lower electrode pad BCP. The lower electrode pad BCP may protrude onto the interposer interconnection layer 620, and the upper surface of the lower electrode pad BCP may be coplanar with an upper surface of the interposer interconnection layer 620. The lower electrode pad BCP may be electrically connected to the interposer interconnection pattern 624. The capacitor dielectric film CIL may cover the upper surfaces and side surfaces of the lower electrodes BE, and the upper surface of the lower electrode pad BCP exposed between the lower electrodes BE. The upper electrode TE may conformally cover the capacitor dielectric film CIL. The lower electrodes BE may share one upper electrode TE. Unlike FIG. 3, the upper electrode pad TCP may not be provided. A portion of a lower surface of the upper electrode TE may be exposed onto the interposer core 610. Here, the upper electrode TE may be electrically connected to the interposer interconnection pattern 624 through a via on the lower surface of the upper electrode TE. A height of the capacitor device CAP may be about 15 μm to about 50 μm. A height of the interposer substrate 600 may be about 90 μm to about 150 μm.

It is described with reference to FIGS. 1 to 4 that the chip stack CS and the first semiconductor chip 300 are mounted on the substrate 100 by using connection terminals, but the inventive concepts are not limited thereto.

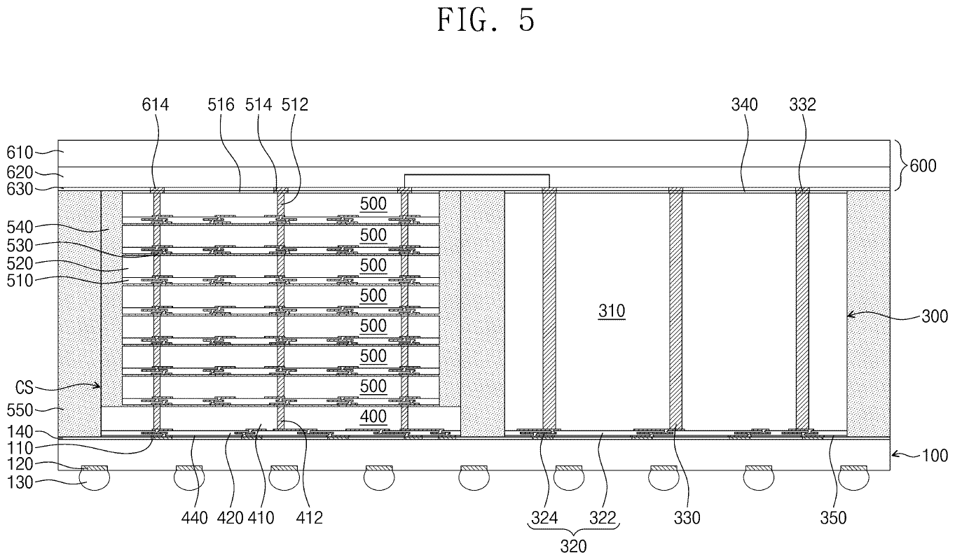

FIG. 5 is a cross-sectional view illustrating a semiconductor package according to some example embodiments of the inventive concepts. Referring to FIG. 5, the chip stack CS and the first semiconductor chip 300 may be provided on the first substrate 100. Here, a configuration and arrangement of the first substrate 100, the chip stack CS, and the first semiconductor chip 300 may be substantially similar to those described with reference to FIG. 1. The chip stack CS and the first substrate 100 may be hybrid bonded, and the first semiconductor chip 300 and the first substrate 100 may be hybrid bonded.

The first semiconductor chip 300 may be mounted on the first substrate 100. The second insulating film 340 of the first semiconductor chip 300 and the first insulating film 140 of the first substrate 100 may be bonded on an interface of the first semiconductor chip 300 and the first substrate 100. Here, the third insulating film 350 and the first insulating film 140 may form oxide, nitride, or oxynitride hybrid bonding. The third insulating film 350 and the first insulating film 140 bonded to each other may have a continuous configuration, and a boundary surface between the second insulating film 340 and the first insulating film 140 may not be viewed. The third insulating film 350 and the first insulating film 140 may be formed of the same material and provided as one component. However, the inventive concepts are not limited thereto. The third insulating film 350 and the first insulating film 140 may be formed of different materials, and the third insulating film 350 and the first insulating film 140 may not have a continuous configuration.

The first semiconductor chip 300 and the first substrate 100 may be in contact with each other. The first chip lower pads of the first semiconductor chip 300 and the upper first substrate pads 110 of the first substrate 100 may be in contact, for example direct contact, with each other on an interface of the first semiconductor chip 300 and the first substrate 100. For example, the first chip lower pads and the upper first substrate pads 110 may form intermetallic hybrid bonding. The first chip lower pads and the upper first substrate pads 110 bonded to each other may have a continuous configuration, and a boundary surface between the first chip lower pads and the upper first substrate pads 110 may not be viewed. For example, the first chip lower pads and the upper first substrate pads 110 may be formed of the same material and provided as one component. For example, the first chip lower pads and the upper first substrate pads 110 may be bonded to each other and integrally formed.

The chip stack CS may be mounted on the first substrate 100. The fourth insulating film 440 of the chip stack CS and the first insulating film 140 of the first substrate 100 may be bonded to each other on an interface of the chip stack CS and the first substrate 100. Here, the fourth insulating film 440 and the first insulating film 140 may form oxide, nitride, or oxynitride hybrid bonding. The fourth insulating film 440 and the first insulating film 140 bonded to each other may have a continuous configuration, and a boundary surface between the fourth insulating film 440 and the first insulating film 140 may not be viewed. The fourth insulating film 440 and the first insulating film 140 may be formed of the same material and provided as one component. However, the inventive concepts are not limited thereto. The fourth insulating film 440 and the first insulating film 140 may be formed of different materials, and the fourth insulating film 440 and the first insulating film 140 may not have a continuous configuration.

The chip stack CS and the first substrate 100 may be in contact with each other. The base pads of the chip stack CS and the upper first substrate pads 110 of the first substrate 100 may be in contact, for example direct contact, with each other on an interface of the chip stack CS and the first substrate 100. For example, the base pads and the upper first substrate pads 110 may form intermetallic hybrid bonding. The base pads and the upper first substrate pads 110 bonded to each other may have a continuous configuration, and a boundary surface between the base pads and the upper first substrate pads 110 may not be viewed. For example, the base pads and the upper first substrate pads 110 may be formed of the same material and provided as one component. For example, the base pads and the upper first substrate pads 110 may be bonded to each other and integrally formed.

It is described with reference to FIGS. 1 to 5 that the interposer substrate 600 includes the interposer interconnection layer 620 and the interposer core 610 provided on the upper surface of the interposer interconnection layer 620, but the inventive concepts are not limited thereto.

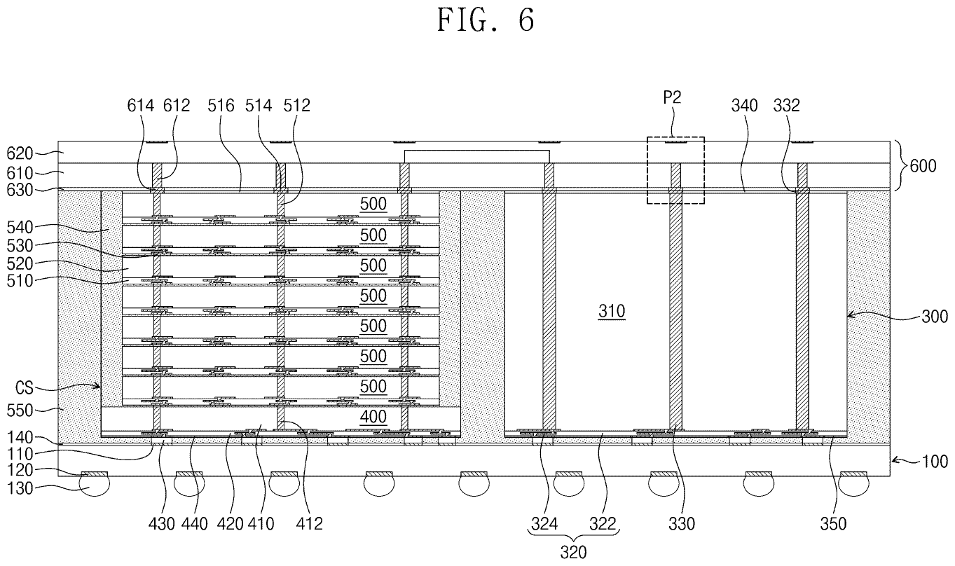

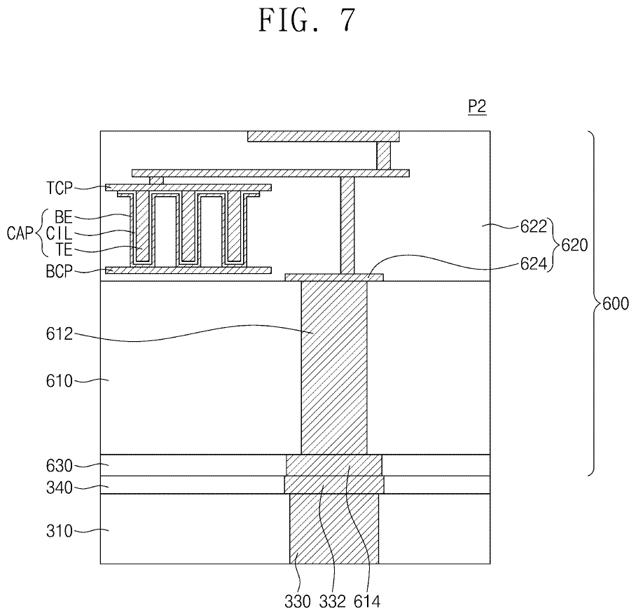

FIG. 6 is a cross-sectional view illustrating a semiconductor package according to some example embodiments of the inventive concepts. FIG. 7 is an enlarged view, of portion P2 of FIG. 6, for partially describing a semiconductor package according to some example embodiments of the inventive concepts. Referring to FIGS. 6 and 7, the first substrate 100, the chip stack CS, and the first semiconductor chip 300 may be provided. The first substrate 100, the chip stack CS, and the first semiconductor chip 300 may be respectively substantially the same as those described with reference to FIG. 1. For example, the chip stack CS and the first semiconductor chip 300 may be mounted on the first substrate 100. The chip stack CS and the first semiconductor chip 300 may be spaced apart in the first direction D1. The interposer substrate 600 may be provided on the upper surfaces of the chip stack CS and the first semiconductor chip 300. Unlike FIGS. 1 to 5, the interposer substrate 600 may include the interposer core 610 and the interposer interconnection layer 620 on the interposer core 610.

The interposer core 610 may include a semiconductor material. For example, the interposer core 610 may include silicon (Si). Interposer through vias 612 penetrating the interposer core 610 may be provided. The interposer through vias 612 may penetrate the interposer core 610 and electrically connect the interposer interconnection layer 620 and the lower interposer pads 614 to be described later. Upper surfaces of the interposer through vias 612 may be exposed onto an upper surface of the interposer core 610. The interposer through vias 612 may include at least one metal of aluminum (Al), copper (Cu), tungsten (W), molybdenum (Mo), or cobalt (Co). The lower interposer pads 614 may be provided on a lower surface of the interposer core 610. The lower interposer pads 614 may be each provided on a lower surface of a corresponding interposer through via 612. The lower surfaces of the interposer through vias 612 may be in contact with the lower interposer pads 614. The sixth insulating film 630 may be provided on the lower surface of the interposer core 610. The sixth insulating film 630 may cover the lower surface of the interposer core 610. The sixth insulating film 630 may surround the lower interposer pads 614, on the lower surface of the interposer core 610. The lower interposer pads 614 may be exposed onto a lower surface of the sixth insulating film 630. The sixth insulating film 630 may include silicon oxide (SiOx), silicon nitride (SiNx), or the like.

As shown, the first chip upper pads 332 or the second chip upper pads 514 may be respectively connected to the lower interposer pads 614. The first chip upper pads 332 may be connected to lower surfaces of some of the lower interposer pads 614. The second chip upper pads 514 may be connected to lower surfaces of the remaining lower interposer pads 614. Similarly to FIG. 1, the lower interposer pads 614 and the first chip upper pads 332 may be in contact, for example direct contact, with each other, and the lower interposer pads 614 and the second chip upper pads 514 may be in contact, for example direct contact, with each other. Each of the first chip upper pads 332 and the second chip upper pads 514 may be electrically connected to the interposer interconnection layer 620 through the interposer through via 612.

The interposer interconnection layer 620 may be provided on the upper surface of the interposer core 610. The interposer interconnection layer 620 may have the interposer insulating pattern 622 and the interposer interconnection pattern 624 provided in the interposer insulating pattern 622. The interposer interconnection pattern 624 may be connected to the interposer through vias 612 formed in the interposer core 610. For example, the exposed upper surface of the interposer through via 612 may be in contact with the interposer interconnection pattern 624. The capacitor device CAP may be provided in the interposer interconnection layer 620. The capacitor device CAP may be substantially the same as or similar to that described with reference to FIG. 3. For example, the capacitor device CAP may be formed in the interposer insulating pattern 622. The capacitor device CAP may include the lower electrode BE, the upper electrode TE, and the capacitor dielectric film CIL between the lower electrode BE and the upper electrode TE. A height of the capacitor device CAP may be about 1 μm to about 5 μm. The capacitor device CAP may be electrically connected to the interposer interconnection pattern 624 through the upper electrode pad TCP. The capacitor device CAP may be in contact with the upper electrode pad TCP. The capacitor device CAP may be electrically connected to the interposer interconnection pattern 624 through the upper electrode pad TCP. The lower electrode pad BCP may be disposed on lower surfaces of the upper electrodes TE. An upper surface of the lower electrode pad BCP may be in contact with the lower electrode BE. The lower electrode BE may be electrically connected to the lower electrode pad BCP. The lower electrode pad BCP may have a plate shape. Although not shown, the lower electrode pad BCP may be electrically connected to the interposer interconnection pattern 624. The capacitor device CAP may be electrically connected to the first semiconductor chip 300 and the chip stack CS through the upper and lower electrode pads TCP and BCP, the interposer interconnection pattern 624, the interposer through via 612, and the lower interposer pad 614. The capacitor device CAP may be located above the first semiconductor chip 300. The capacitor device CAP may vertically overlap the first semiconductor chip 300. However, the inventive concepts are not limited thereto, and the capacitor device CAP may be provided in plurality. The plurality of capacitor devices CAP may be respectively located above the chip stack CS and the first semiconductor chip 300.

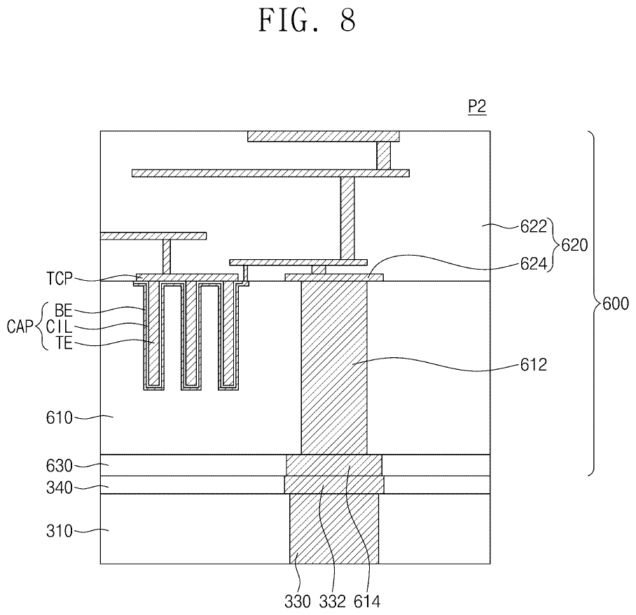

It is described with reference to FIG. 7 that the capacitor device CAP is provided in the interposer interconnection layer 620, but the inventive concepts are not limited thereto. FIG. 8 is an enlarged view, of portion P2 of FIG. 6, for partially describing a semiconductor package according to embodiments of the inventive concept.

Referring to FIG. 8, the capacitor device CAP may be provided in the interposer core 610. A configuration and a structure of the capacitor device CAP may be substantially the same as or similar to those described with reference to FIGS. 6 and 7. For example, the capacitor device CAP may include the lower electrode BE, the upper electrode TE, and the capacitor dielectric film between the lower electrode BE and the upper electrode TE. The capacitor device CAP may be electrically connected to the interposer interconnection layer 620 through the upper electrode pad TCP. However, unlike FIG. 3, the capacitor device CAP may be provided in the interposer core 610. Upper surfaces of the upper electrodes TE may be substantially coplanar with each other and may be in contact with and electrically connected to a lower surface of the upper electrode pad TCP. The lower surface of the upper electrode pad TCP may be coplanar with the lower surface of the interposer core 610. The upper electrode pad TCP may be connected to the interposer interconnection pattern 624 through a via. The lower electrode pad BCP may not be provided on a lower surface of the capacitor device CAP. Here, the lower electrode BE may be electrically connected to the interposer interconnection pattern 624 through a via. A height of the capacitor device CAP may be about 15 μm to about 50 μm. A height of the interposer substrate 600 may be about 90 μm to about 150 μm.

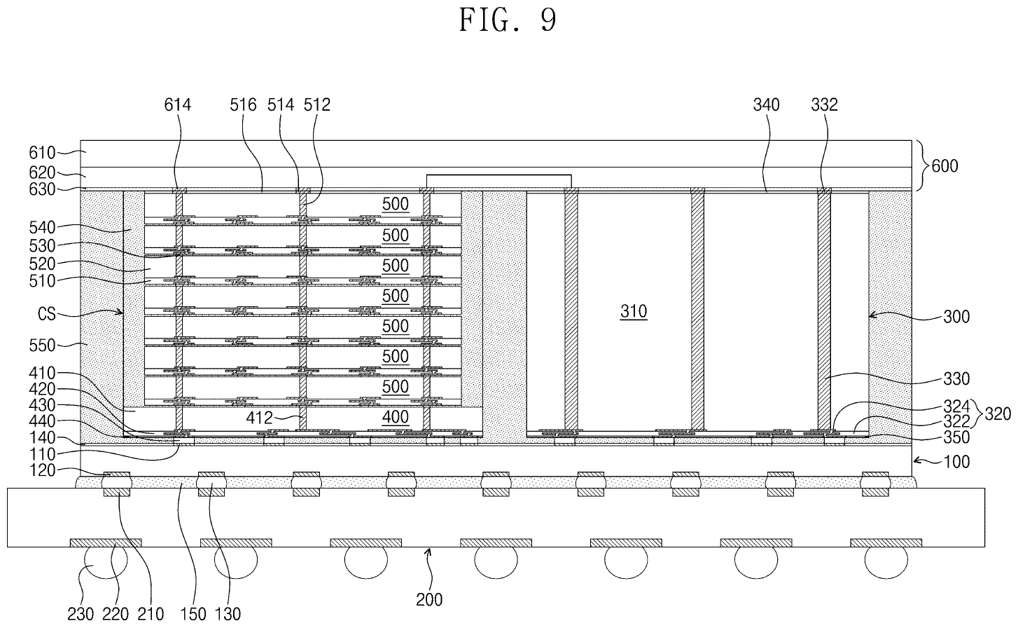

FIG. 9 is a cross-sectional view illustrating a semiconductor package according to some example embodiments of the inventive concepts. Referring to FIG. 9, a second substrate 200 may be provided. The first substrate 100, the chip stack CS, the first semiconductor chip 300, and the interposer substrate 600 may be provided on an upper surface of the second substrate 200. In other words, the semiconductor package of FIG. 9 may be substantially the same as the semiconductor package of FIG. 1 mounted on the second substrate 200.

The second substrate 200 may be a printed circuit board (PCB) having an upper surface and a lower surface opposed to the upper surface. Here, the second substrate 200 may have an internal interconnection pattern provided in the second substrate 200. For example, the second substrate 200 may have a structure in which an insulating pattern and the internal interconnection pattern are alternately stacked. Upper second substrate pads 210 may be provided on an upper surface of the second substrate 200. The upper second substrate pads 210 may be separate pads electrically connected to the internal interconnection pattern, or a portion of the internal interconnection pattern exposed onto the upper surface of the second substrate 200. The upper second substrate pads 210 may be coplanar with the upper surface of the second substrate 200 and exposed onto the second substrate 200. However, the inventive concepts are not limited thereto, and the upper second substrate pads 210 may protrude onto the upper surface of the second substrate 200.

Lower second substrate pads 220 and external connection terminals 230 may be provided on a lower surface of the second substrate 200. The lower second substrate pads 220 may be separate pads disposed on the lower surface of the second substrate 200 and connected to the internal interconnection pattern of the second substrate 200, or a portion of the conductive pattern exposed onto the lower surface of the second substrate 200. The external connection terminals 230 may be respectively disposed on lower surfaces of the lower second substrate pads 220 corresponding thereto. The external connection terminals 230 may include a solder ball, solder bump, or the like. The upper second substrate pads 210 and the lower second substrate pads 220 may include a conductive material such as metal.

The semiconductor package of FIG. 2 may be mounted on the upper surface of the second substrate 200. Lower surfaces of the substrate connection terminals 130 of the first substrate 100 may be in contact with upper surfaces of the lower second substrate pads 220. The first substrate 100 may be electrically connected to the second substrate 200 through the substrate connection terminals 130. The chip stack CS and the first semiconductor chip 300 may be electrically connected to the second substrate 200 through the first substrate 100. An underfill film 150 may be provided between the first substrate 100 and the second substrate 200. The underfill film 150 may fill a space between the first substrate 100 and the second substrate 200 and surround the substrate connection terminals 130. The first substrate 100 may redistribute the chip stack CS and the first semiconductor chip 300, between the chip stack CS and the second substrate 200 and between the first semiconductor chip 300 and the second substrate 200.

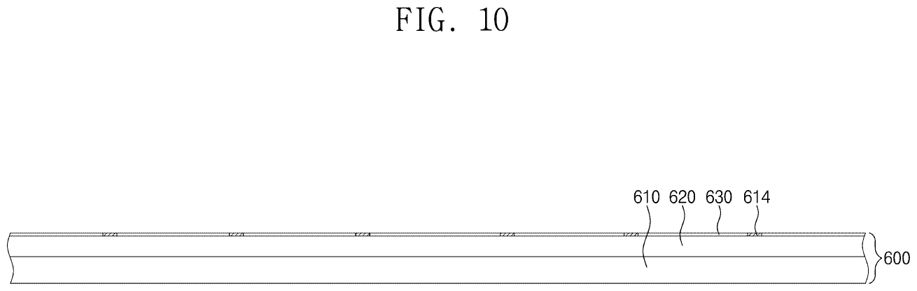

FIGS. 10 to 13 are cross-sectional views for describing a method for manufacturing a semiconductor package according to embodiments of the inventive concept.

Referring to FIG. 10, an interposer substrate 600 may be formed. An interposer core 610 may be provided. The interposer core 610 may include silicon (Si). An interposer interconnection layer 620 may be formed on an upper surface of the interposer core 610. A sixth insulating film 630 may be formed by depositing an insulating material on an upper surface of the interposer interconnection layer 620. Holes for providing lower interposer pads 614 may be formed by patterning the sixth insulating film 630. The lower interposer pads 614 that fill the holes may be formed on the sixth insulating film 630. The lower interposer pads 614 may be formed through a plating process. Upper surfaces of the lower interposer pads 614 may be exposed onto an upper surface of the sixth insulating film 630.

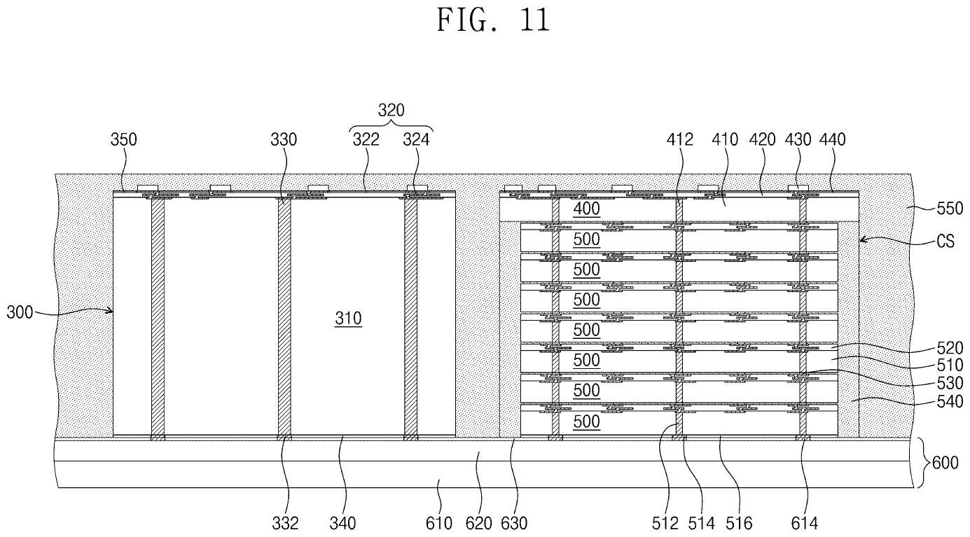

Referring to FIG. 11, a chip stack CS and a first semiconductor chip 300 may be mounted on the resultant structure of FIG. 10. Here, the chip stack CS and the first semiconductor chip 300 may be the same as or similar to those described with reference to FIG. 2. An inactive surface of a first semiconductor substrate 310 may be provided on an upper surface of the interposer substrate 600 to face each other. For example, the first semiconductor chip 300 may be disposed upside down such that exposed upper surfaces of the lower interposer pads 614 face first chip upper pads 332. In other words, the interposer interconnection layer 620 and the inactive surface of the first semiconductor substrate 310 may be disposed to face each other such that the first chip upper pads 332 and the lower interposer pads 614 are vertically aligned.

The chip stack CS may be horizontally spaced apart from the first semiconductor chip 300. An uppermost second semiconductor chip 500 of the chip stack CS may be disposed to face the interposer interconnection layer 620. For example, the chip stack CS may be disposed upside down such that the exposed upper surfaces of the lower interposer pads 614 face second chip upper pads 514. In other words, the interposer interconnection layer 620 and an inactive surface of an uppermost second semiconductor substrate 510 may be disposed to face each other such that the second chip upper pads 514 and the lower interposer pads 614 are vertically aligned.

Thereafter, the first semiconductor chip 300 and the interposer substrate 600 may be in contact with each other, and the chip stack CS and the interposer substrate 600 may be in contact with each other. A heat treatment process may be performed on the first semiconductor chip 300, the chip stack CS, and the interposer substrate 600. The heat treatment process may include applying heat to the first semiconductor chip 300, the chip stack CS, and the interposer substrate 600. The heat treatment process may further include bonding and integrally forming the second chip upper pads 514 and the lower interposer pads 614 by the heat and bonding and integrally forming the first chip upper pads 332 and the lower interposer pads 614 by the heat.

The first chip upper pads 332 and the lower interposer pads 614 may be naturally bonded to each other. Specifically, the first chip upper pads 332 and the lower interposer pads 614 may be formed of the same material (for example, copper (Cu), or the like), and peripheral first chip upper pads 332 and lower interposer pads 614 may be bonded by an intermetallic hybrid bonding process (for example, Cu—Cu hybrid bonding) caused by surface activation on a first bonding surface of the first chip upper pads 332 and the lower interposer pads 614 in contact with each other. A second insulating film 340 and the sixth insulating film 630 may be bonded by the heat treatment process. For example, the second insulating film 340 and the sixth insulating film 630 may be bonded to each other and integrally formed.

The second chip upper pads 514 and the lower interposer pads 614 may be naturally bonded to each other. Specifically, the second chip upper pads 514 and the lower interposer pads 614 may be formed of the same material (for example, copper (Cu), or the like), and peripheral second chip upper pads 514 and lower interposer pads 614 may be bonded by an intermetallic hybrid bonding process (for example, Cu—Cu hybrid bonding) caused by surface activation on a second bonding surface of the second chip upper pads 514 and lower interposer pads 614 in contact with each other. A fifth insulating film 516 and the sixth insulating film 630 may be bonded by the heat treatment process. For example, the fifth insulating film 516 and the sixth insulating film 630 may be bonded to each other and integrally formed.

A second molding film 550 surrounding, on the interposer substrate 600, the chip stack CS and the first semiconductor chip 300 may be provided. The second molding film 550 may fill a space between the chip stack CS and the first semiconductor chip 300. For example, the second molding film 550 may be formed by applying an insulating material and then curing the insulating material. The second molding film 550 may cover the chip stack CS and the first semiconductor chip 300.

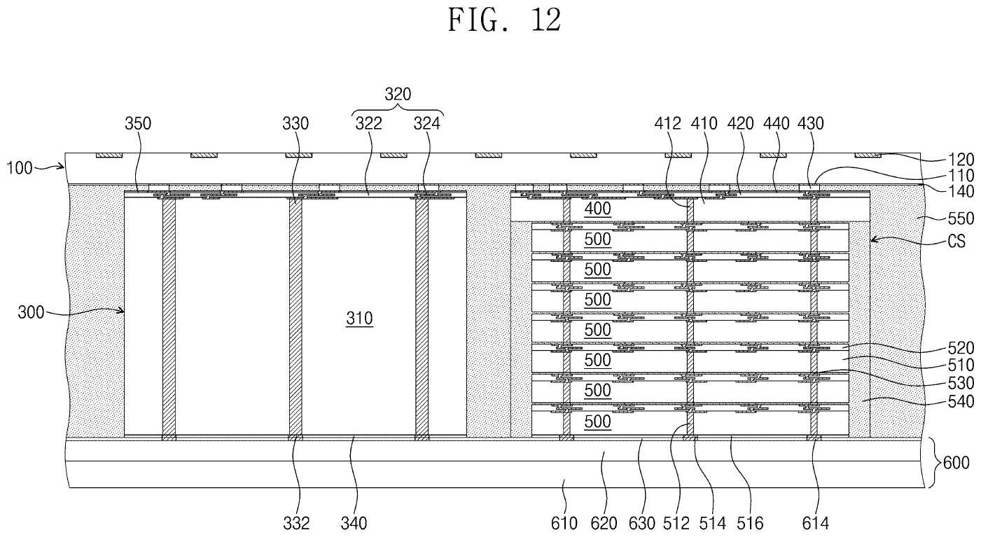

Referring to FIG. 12, a first substrate 100 may be provided on an upper surface of the second molding film 550. Firstly, a grinding process may be performed on the upper surface of the second molding film 550. Upper surfaces of first connection terminals disposed on an upper surface of the first semiconductor chip 300 and upper surfaces of second connection terminals 430 disposed on an upper surface of the chip stack CS may be exposed by the grinding process. A ground upper surface of the second molding film 550 may be coplanar with the upper surfaces of the first connection terminals and second connection terminals 430. An insulating layer may be formed on the ground upper surface of the second molding film 550. One insulating pattern may be formed by patterning the insulating layer. One substrate interconnection layer may be formed by forming a conductive layer on the insulating pattern and then forming one conductive pattern by patterning the conductive layer. The first substrate 100 having a plurality of substrate interconnection layers may be formed by repeatedly performing a process of forming the substrate interconnection layer. The interconnection pattern provided to a lowermost substrate interconnection layer may be upper first substrate pads 110. The upper first substrate pads 110 of the first substrate 100 may be respectively connected to the first connection terminals and the second connection terminals 430 corresponding thereto. The interconnection pattern provided to an uppermost substrate interconnection layer may be lower first substrate pads 120.

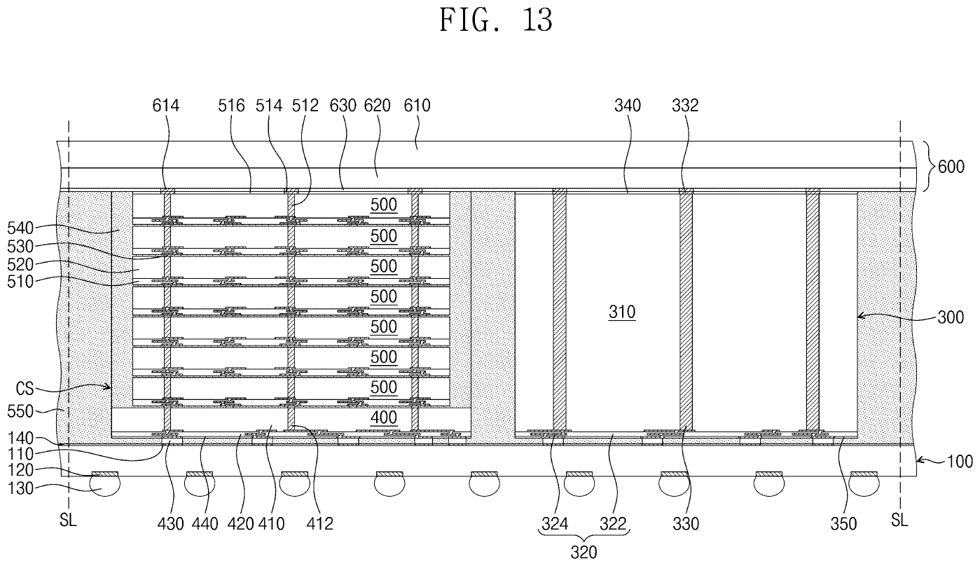

Referring to FIG. 13, the resultant structure of FIG. 12 may be turned upside down. Accordingly, the first semiconductor chip 300 and the chip stack CS may be located on an upper surface of the first substrate 100. The interposer substrate 600 may be located on upper surfaces of the first semiconductor chip 300 and the chip stack CS. Substrate connection terminals 130 may be disposed on a lower surface of the first substrate 100. The substrate connection terminals 130 may be provided on lower surfaces of the lower first substrate pads 120. For example, the substrate connection terminals 130 such as solder balls or solder bumps may be attached onto the lower surfaces of the lower first substrate pads 120. Thereafter, one substrate may be formed by performing a sawing process along a sawing line SL. A semiconductor package separated by the sawing process may correspond to the semiconductor package of FIG. 2.

In a semiconductor package according to some example embodiments of the inventive concepts, a passive element may be located in an upper interposer substrate, and thus may be adjacently connected to a semiconductor chip disposed on a lower surface of the upper interposer substrate. Accordingly, the semiconductor package having improved electrical characteristics may be provided.

In addition, in a semiconductor package according to some example embodiments of the inventive concepts, the passive element may be located in the upper interposer substrate, and thus there may be no need to attach a separate external passive element, thereby providing a miniaturized semiconductor package.

What is claimed is:

1. A semiconductor package comprising:
a redistribution substrate;
a first semiconductor chip on the redistribution substrate, the first semiconductor chip including first chip upper pads on an upper surface of a first semiconductor substrate;
a chip stack on the redistribution substrate, the chip stack being spaced apart from the first semiconductor chip; and
an interposer substrate covering an upper surface of the chip stack and an upper surface of the first semiconductor chip,
wherein the chip stack includes second semiconductor chips which are vertically stacked, and an uppermost second semiconductor chip among the second semiconductor chips includes second chip upper pads on an upper surface of the uppermost second semiconductor chip,
the interposer substrate includes interposer pads on a lower surface of the interposer substrate, and
the interposer pads are in contact with the first chip upper pads and the second chip upper pads.

2. The semiconductor package of claim 1, wherein the first semiconductor chip comprises:
first through vias penetrating the first semiconductor substrate,
an integrated circuit on a lower surface of the first semiconductor substrate,
first chip lower pads on the lower surface of the first semiconductor substrate, and
the first chip upper pads being connected to the first through vias, on the upper surface of the first semiconductor substrate.

3. The semiconductor package of claim 2, wherein the first semiconductor chip further comprises:
a first insulating film surrounding the first chip upper pads, on the upper surface of the first semiconductor substrate,
the interposer substrate further includes a second insulating film surrounding the interposer pads, on the lower surface of the interposer substrate, and
the first insulating film and the second insulating film are in contact with each other.

4. The semiconductor package of claim 3, further comprising:
a molding film surrounding the chip stack and the first semiconductor chip, on the redistribution substrate, wherein
an upper surface of the molding film is coplanar with the upper surface of the chip stack and the upper surface of the first semiconductor chip, and
the upper surface of the molding film is in contact with a lower surface of the second insulating film.

5. The semiconductor package of claim 1, wherein
the first semiconductor chip is provided in plurality,
the first semiconductor chips are spaced apart from each other, and
the first semiconductor chips are electrically connected through the interposer substrate.

6. The semiconductor package of claim 1, wherein the interposer substrate vertically overlaps all of the chip stack and the first semiconductor chip.

7. The semiconductor package of claim 1, wherein
the interposer substrate further includes at least one capacitor device in the interposer substrate, and
the capacitor device includes,
an upper electrode;
a capacitor dielectric film covering the upper electrode with a uniform thickness; and
a lower electrode covering the upper electrode, on the capacitor dielectric film.

8. The semiconductor package of claim 7, wherein
the interposer substrate includes an insulating pattern and an interconnection pattern in the insulating pattern,
the capacitor device is electrically connected to the interconnection pattern, in the insulating pattern, and
a height of the capacitor device is about 1 μm to about 5 μm.

9. The semiconductor package of claim 7, wherein
the interposer substrate includes an interposer interconnection layer and an interposer core on the interposer interconnection layer,
the capacitor device further includes a lower electrode pad on a lower surface of the capacitor device,
the capacitor device is in the interposer core, and
the lower electrode pad protrudes onto a lower surface of the interposer core and is connected to the interposer interconnection layer.

10. The semiconductor package of claim 7, wherein the capacitor device is above the first semiconductor chip.

11. The semiconductor package of claim 7, wherein
the capacitor device is provided in plurality, and
the plurality of capacitor devices are respectively above the first semiconductor chip and the chip stack.

12. A semiconductor package comprising:
a substrate;
a first semiconductor chip and a chip stack spaced apart from each other on the substrate; and
an interposer substrate on upper surfaces of the first semiconductor chip and the chip stack, wherein
the first semiconductor chip includes,
a first through via penetrating a first semiconductor substrate,
a first integrated circuit on a first active surface of the first semiconductor substrate, and
a first chip pad on a first inactive surface of the first semiconductor substrate,
the chip stack includes second semiconductor chips stacked in a direction perpendicular to an upper surface of the substrate,
the second semiconductor chips each include,
a second through via penetrating a second semiconductor substrate,
a second integrated circuit on a second active surface of the second semiconductor substrate, and
a second chip pad on a second inactive surface of the second semiconductor substrate,
the interposer substrate includes a capacitor device in the interposer substrate and interposer pads on a lower surface of the interposer substrate, and
some of the interposer pads are in contact with the first chip pad, and remaining interposer pads are in contact with the second chip pad of the chip stack.

13. The semiconductor package of claim 12, wherein
the substrate includes substrate pads on the upper surface of the substrate,
the first semiconductor chip includes a third chip pad on the first active surface of the first semiconductor substrate,
the chip stack includes a fourth chip pad on a lower surface of the chip stack,
some of the substrate pads are in contact with the third chip pad, and
remaining substrate pads are in contact with the fourth chip pad.

14. The semiconductor package of claim 12, wherein the capacitor device includes,
an upper electrode;
a lower electrode spaced apart from the upper electrode; and
a dielectric film between the upper electrode and the lower electrode, and
a height of the capacitor device is about 1 μm to about 5 μm.

15. The semiconductor package of claim 12, wherein
the chip stack is provided in plurality,
the chip stacks are horizontally spaced apart from each other on the upper surface of the substrate,
the first semiconductor chip is between any two of the chip stacks,
the semiconductor package further includes a molding film surrounding the first semiconductor chip and the chip stacks, and
the interposer substrate covers the upper surface of the first semiconductor chip, upper surfaces of the chip stacks, and an upper surface of the molding film.

16. The semiconductor package of claim 12, wherein a height of the interposer substrate is 40 μm to 70 μm.

17. The semiconductor package of claim 12, wherein
the interposer substrate includes an interposer interconnection layer and an interposer core on the interposer interconnection layer, and
the interposer core includes silicon.

18. A semiconductor package comprising:
a substrate;
an external connection terminal on a lower surface of the substrate;
a redistribution substrate on an upper surface of the substrate;
a first semiconductor chip on the redistribution substrate, the first semiconductor chip including first chip pads on an upper surface of the first semiconductor chip;
a chip stack on the redistribution substrate and spaced apart from the first semiconductor chip; and
an interposer substrate covering an upper surface of the chip stack and the upper surface of the first semiconductor chip,
wherein the chip stack includes second semiconductor chips which are vertically stacked, and an uppermost second semiconductor chip among the second semiconductor chips includes second chip pads on an upper surface of the uppermost second semiconductor chip,
the interposer substrate includes,
an interposer interconnection layer,
an interposer core on the interposer interconnection layer,
at least one capacitor device in the interposer interconnection layer, and
interposer pads on a lower surface of the interposer interconnection layer,
the capacitor device includes,
an upper electrode,
a lower electrode spaced apart from the upper electrode,
a dielectric film between the upper electrode and the lower electrode, and
an upper electrode pad on an upper surface of the upper electrode, and
the upper electrode pad is electrically connected to the capacitor device and an interconnection pattern in the interposer interconnection layer.

19. The semiconductor package of claim 18, wherein
the first semiconductor chip includes a first insulating film surrounding the first chip pads, on the upper surface of the first semiconductor chip,
the interposer substrate includes a second insulating film surrounding the interposer pads, on a lower surface of the interposer substrate,
the first insulating film and the second insulating film are in contact with each other,
some of the interposer pads are in contact with the first chip pads, and
remaining interposer pads are in contact with the second chip pads.

20. The semiconductor package of claim 18, wherein
the interposer core includes silicon, and
a height of the interposer substrate is about 40 μm to about 70 μm.
